(19) United States
(12) Patent Application Publication
(10) Pub. No.: US 2023/0155569 A1
(43) Pub. Date: May 18, 2023

(54) ACOUSTIC WAVE DEVICE

(71) Applicant: Murata Manufacturing Co., Ltd., Nagaokakyo-shi (JP)

(72) Inventor: Takashi YAMANE, Nagaokakyo-shi (JP)

(21) Appl. No.: 18/099,987

(22) Filed: Jan. 23, 2023

Related U.S. Application Data
(63) Continuation of application No. PCT/JP2021/027694, filed on Jul. 27, 2021.

(30) Foreign Application Priority Data
Jul. 27, 2020 (JP) 2020-126674

(51) Int. Cl. H03H 9/17; H03H 9/13; H03H 9/02

(52) U.S. Cl. CPC H03H 9/173; H03H 9/132; H03H 9/02031

(57) ABSTRACT

An acoustic wave device includes an IDT electrode with an inclined IDT structure on a piezoelectric substrate. An intersection region, where a first electrode finger and a second electrode finger overlap each other when viewed in an acoustic wave propagation direction, includes a central region and first and second low acoustic velocity regions on both sides of the central region. The first and second low acoustic velocity regions have an asymmetric shape about a central axis extending in a length direction of the first and second electrode fingers.

### CROSS REFERENCE TO RELATED APPLICATIONS

This application claims the benefit of priority to Japanese Patent Application No. 2020-126674 filed on Jul. 27, 2020 and is a Continuation Application of PCT Application No. PCT/JP2021/027694 filed on Jul. 27, 2021. The entire contents of each application are hereby incorporated herein by reference.

### BACKGROUND OF THE INVENTION

### 1. Field of the Invention

The present invention relates to an acoustic wave device including an inclined IDT electrode.

### 2. Description of the Related Art

International Publication No. 2015/098756 discloses an acoustic wave device having an inclined IDT electrode, and further having a structure for suppressing a transverse mode. In this acoustic wave device, in order to provide a low acoustic velocity region in an intersection region, an edge portion of an electrode finger is formed as a large-width portion, and is made wider than a width of the electrode finger in a central region.

### SUMMARY OF THE INVENTION

In the acoustic wave device described in International Publication No. 2015/098756, since the large-width portion is provided in the low acoustic velocity region, the transverse mode can be suppressed. However, due to such an electrode structure, another ripple could be generated. In particular, in a case of an acoustic wave resonator, a ripple could appear between a resonant frequency and an anti-resonant frequency.

Preferred embodiments of the present invention provide acoustic wave devices each capable of suppressing a ripple between a resonant frequency and an anti-resonant frequency.

An acoustic wave device according to a preferred embodiment of the present invention includes a piezoelectric substrate, and an IDT electrode provided on the piezoelectric substrate, wherein the IDT electrode includes a first busbar, a second busbar separated from the first busbar, a plurality of first electrode fingers including one end connected to the first busbar, a plurality of second electrode fingers including one end connected to the second busbar, a plurality of first dummy electrodes connected to the second busbar, tip ends of the first dummy electrodes facing tip ends of the first electrode fingers with a second gap interposed therebetween, and a plurality of second dummy electrodes connected to the first busbar, tip ends of the second dummy electrodes facing tip ends of the second electrode fingers with a first gap interposed therebetween, and when a first virtual line connecting the tip ends of the plurality of second electrode fingers is inclined with respect to an acoustic wave propagation direction that is a direction orthogonal to a direction in which the first and second electrode fingers extend, a distance between a tip end of a second electrode finger on one side, of a pair of second electrode fingers included in the second electrode fingers adjacent to any of the first electrode fingers, and a base end of the first electrode finger is shorter than a distance between a tip end of the second electrode finger on another side of the pair and the base end of the first electrode finger, and a direction extending in a direction in which the distance is longer in the first virtual line is an inclination direction, at least one of a projecting portion protruding toward the first electrode finger or the second electrode finger, in at least one of a side opposite to the inclination direction at a tip end of the second electrode finger, a side in the inclination direction at a tip end of the second dummy electrode, a side in the inclination direction of the first electrode finger on an extension in the inclination direction from the tip end of the second dummy electrode, and a side opposite to the inclination direction of the first electrode finger on an extension in the inclination direction from the tip end of the second electrode finger, and a recessed portion in at least one of a side in the inclination direction at the tip end of the second electrode finger, a side opposite to the inclination direction at the tip end of the second dummy electrode, a side opposite to the inclination direction of the first electrode finger positioned on the extension in the inclination direction from the tip end of the second dummy electrode, and a side in the inclination direction of the first electrode finger positioned on the extension in the inclination direction from the tip end of the second electrode finger, is provided.

In another broad aspect of an acoustic wave device according to a preferred embodiment of the present invention includes a piezoelectric substrate, and an IDT electrode on the piezoelectric substrate, wherein the IDT electrode includes a first busbar, a second busbar separated from the first busbar, a plurality of first electrode fingers including one end connected to the first busbar, a plurality of second electrode fingers including one end connected to the second busbar, a plurality of first dummy electrodes connected to the second busbar, tip ends of the first dummy electrodes facing tip ends of the first electrode fingers with a second gap interposed therebetween, and a plurality of second dummy electrodes connected to the first busbar, tip ends of the second dummy electrodes facing tip ends of the second electrode fingers with a first gap interposed therebetween, a first virtual line connecting the tip ends of the plurality of second electrode fingers is inclined with respect to an acoustic wave propagation direction that is a direction orthogonal to a direction in which the first and second electrode fingers extend, a distance between a tip end of a second electrode finger on one side, of a pair of second electrode fingers included in the second electrode fingers adjacent to any first electrode finger included in the first electrode fingers, and a base end of the first electrode finger is shorter than a distance between a tip end of the second electrode finger on an other side of the pair and the base end of the first electrode finger, a side closer to the second electrode finger for which the distance is shorter, of sides of the first electrode finger, and a side closer to the second electrode finger for which the distance is shorter, of sides of a first dummy electrode included in the first dummy electrodes facing the first electrode finger, are each a first side, and a side opposite to the first side is a second side, a distance between a tip end of a first electrode finger on one side, of a pair of first electrode fingers included in the first electrode fingers adjacent to any second electrode finger included in the second electrode fingers, and a base end of the second electrode finger is shorter than a distance between a tip end of the first electrode finger on another side of the pair and the base end of the second electrode finger, a side closer to the first electrode finger for which the distance is shorter, of sides of the second electrode finger, and a side closer to the first electrode finger for which the distance is shorter, of sides of a second dummy electrode included in the second dummy electrodes facing the second electrode finger, are each a second side, and a side opposite to the second side is a first side, a line connecting respective centers of first gaps, each being the first gap interposed between the tip ends, is a second virtual line, of a portion closer to the first gap of the second dummy electrode, a region closer to the first side is a first region and a region closer to the second side is a second region, of a portion closer to the first gap of the second electrode finger, a region closer to the first side is a fifth region and a region closer to the second side is a sixth region, and in the first electrode finger that is adjacent, in a portion closer to the first busbar with respect to the second virtual line, a region closer to the first side is a third region and a region closer to the second side is a fourth region, and in the first electrode finger, in a portion closer to the second busbar with respect to the second virtual line, a region closer to the first side is a seventh region and a region closer to the second side is an eighth region, and in the first region, the third region, the sixth region, and the eighth region, an angle defined by the first side or the second side in each region, and the first virtual line is an acute angle, and in the second region, the fourth region, the fifth region, and the seventh region, an angle defined by the first side or the second side positioned in each region, and the first virtual line is an obtuse angle, and at least one of a recessed portion provided in at least one region of the first region, the third region, the sixth region, and the eighth region, and a projecting portion provided in at least one region of the second region, the fourth region, the fifth region, and the seventh region is provided.

According to preferred embodiments of the present invention, it is possible to provide acoustic wave devices each capable of suppressing a ripple between a resonant frequency and an anti-resonant frequency.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A is a schematic plan view for describing an electrode structure of an acoustic wave device according to a first preferred embodiment of the present invention and FIG. 1B is an enlarged view of a main portion thereof.

FIG. 2 is a schematic plan view illustrating a main portion of an IDT electrode for describing first to eighth regions.

FIG. 3 is a partially cutaway enlarged plan view for describing a modified example of the first preferred embodiment of the present invention.

FIG. 4 is a front sectional view of the acoustic wave device according to the first preferred embodiment of the present invention.

FIG. 5 is a schematic plan view for describing a displacement distribution in an existing acoustic wave device.

FIG. 6 is an enlarged plan view for describing a relationship between the displacement distribution in the existing acoustic wave device and a shape of an electrode finger.

FIG. 7 is a schematic plan view for describing a main portion of the acoustic wave device according to the first preferred embodiment of the present invention.

FIG. 8 is a graph showing impedance-frequency characteristics of Example 1 and Comparative Example 1.

FIG. 9 is a graph showing return loss characteristics of Example 1 and Comparative Example 1.

FIG. 10 is a front sectional view for describing an acoustic wave device according to a second preferred embodiment of the present invention.

FIG. 11 is a front sectional view for describing an acoustic wave device according to a third preferred embodiment of the present invention.

### DETAILED DESCRIPTION OF THE PREFERRED EMBODIMENTS

Hereinafter, specific preferred embodiments of the present invention will be described with reference to the accompanying drawings to clarify the present invention.

The preferred embodiments described in the present specification are merely examples, and partial replacement or combination of configurations is possible between different preferred embodiments.

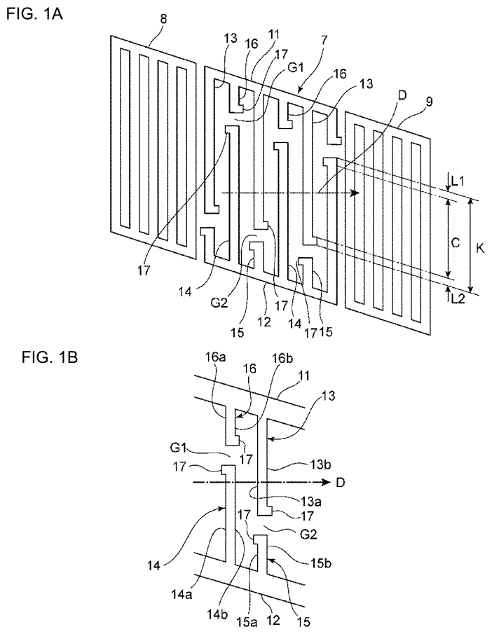

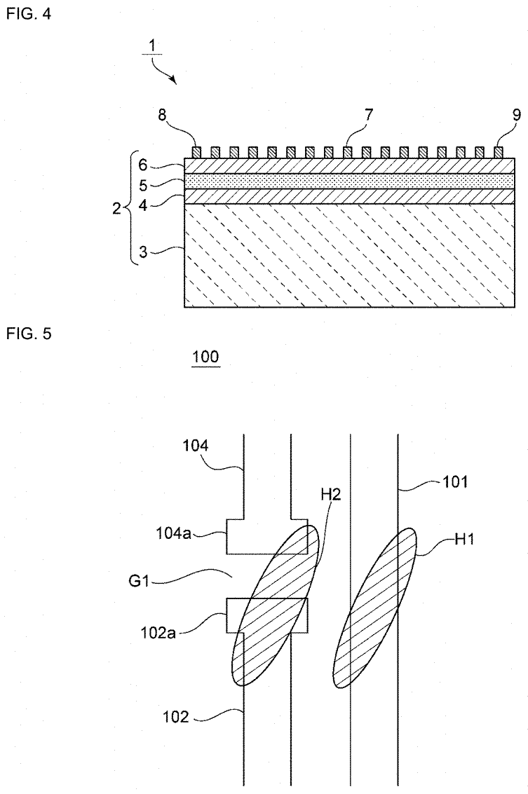

FIG. 1A is a schematic plan view illustrating an electrode structure of an acoustic wave device according to a first preferred embodiment of the present invention and FIG. 1B is an enlarged view of a main portion thereof. Further, FIG. 4 is a front sectional view of the acoustic wave device according to the first preferred embodiment.

As illustrated in FIG. 4, an acoustic wave device 1 includes a piezoelectric substrate 2. An IDT electrode 7 and reflectors 8 and 9 are provided on the piezoelectric substrate 2. As a result, a one-port-type acoustic wave resonator is provided.

The piezoelectric substrate 2 has a structure in which a support substrate 3, a high acoustic velocity material layer 4, a low acoustic velocity material layer 5, and a piezoelectric film 6 are laminated in this order. The support substrate 3 is made of an appropriate semiconductor or dielectric material such as Si or alumina.

The piezoelectric film 6 is made of a piezoelectric single crystal such as LiTaO3. The high acoustic velocity material layer 4 is made of a high acoustic velocity material by which acoustic velocity of a bulk wave propagating therethrough is higher than acoustic velocity of an acoustic wave propagating through the piezoelectric film 6. As such a high acoustic velocity material, various materials can be used such as aluminum oxide, silicon carbide, silicon nitride, silicon oxynitride, silicon, sapphire, lithium tantalate, lithium niobate, quartz, alumina, zirconia, cordierite, mullite, steatite, forsterite, magnesia, a diamond-like carbon (DLC) film or diamond, a medium containing the above-described material as a main component, and a medium containing a mixture of the above-described materials as a main component.

The low acoustic velocity material layer 5 is made of a low acoustic velocity material by which acoustic velocity of a bulk wave propagating therethrough is lower than acoustic velocity of a bulk wave propagating through the piezoelectric film 6. As such a low acoustic velocity material, various materials can be used such as silicon oxide, glass, silicon oxynitride, tantalum oxide, a compound obtained by adding fluorine, carbon, boron, hydrogen, or a silanol group to silicon oxide, a medium containing the above-described material as a main component, and the like.

Since the piezoelectric substrate 2 has the structure described above, an acoustic wave excited in the piezoelectric film 6 can be effectively confined in the piezoelectric film 6. Note that, the support substrate 3 may be a high acoustic velocity support substrate formed of a material similar to that of the high acoustic velocity material layer 4. In this case, the piezoelectric substrate 2 need not have the high acoustic velocity material layer 4. That is, the layer configuration of the piezoelectric substrate 2 may be a configuration in which a high acoustic velocity support substrate, a low acoustic velocity material layer, and a piezoelectric film are laminated in this order.

The IDT electrode 7 and the reflectors 8 and 9 are made of an appropriate metal or alloy. A1ternatively, the IDT electrode 7 and the reflectors 8 and 9 may include a multilayer body including a plurality of metal films.

As illustrated in FIGS. 1A and 1B, the IDT electrode 7 has a so-called inclined structure. The IDT electrode 7 has a first busbar 11 and a second busbar 12. In FIGS. 1A and 1B, the first and second busbars 11 and 12 are inclined downward relative to a horizontal direction, while heading from a left side to a right side of the figure. The first busbar 11 and the second busbar 12 are parallel or substantially parallel to each other.

A plurality of first electrode fingers 13 is connected to the first busbar 11. A plurality of second electrode fingers 14 is connected to the second busbar 12. The plurality of first electrode fingers 13 and the plurality of second electrode fingers 14 are interdigitated with each other. On the other hand, a plurality of second dummy electrodes 16 is connected to the first busbar 11. A plurality of first dummy electrodes 15 is connected to the second busbar 12. Respective tip ends of the second dummy electrode 16 and the second electrode finger 14 face each other with a first gap G1 interposed therebetween. Similarly, respective tip ends of the first electrode finger 13 and the first dummy electrode 15 face each other with a second gap G2 interposed therebetween.

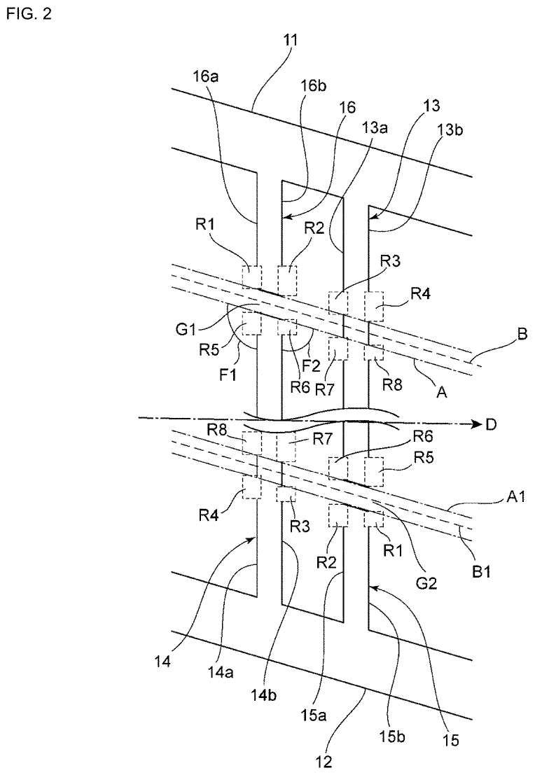

As illustrated in FIG. 2, an acoustic wave propagation direction D is a direction orthogonal to a direction in which the first and second electrode fingers 13 and 14 extend. A first virtual line A is inclined with respect to the acoustic wave propagation direction D. The first virtual line A is a virtual straight line connecting tip ends of the plurality of second electrode fingers 14. Note that, a virtual straight line connecting centers of the plurality of first gaps G1 is a second virtual line B. Further, on a side of the second gap G2, a virtual line connecting tip ends of the plurality of first electrode fingers 13 is a third virtual line A1. A virtual line connecting centers of the plurality of second gaps G2 is a fourth virtual line B1.

The first virtual line A and the third virtual line A1 described above are inclined with respect to the acoustic wave propagation direction D.

As illustrated in FIG. 1A, when viewed along the acoustic wave propagation direction D, a region in which the first electrode finger 13 and the second electrode finger 14 overlap each other is an intersection region K. The intersection region K includes a central region C and first and second low acoustic velocity regions L1 and L2 provided on respective outer side portions of the central region C in a direction in which the first and second electrode fingers 13 and 14 extend. Here, a projecting portion 17, which will be described later, is provided in each of the first and second low acoustic velocity regions L1 and L2, thus achieving low acoustic velocity.

Note that, in the intersection region K, other regions may be further provided on respective outer side portions of the first and second low acoustic velocity regions L1 and L2 in the direction in which the first and second electrode fingers 13 and 14 extend.

In the acoustic wave device 1, high acoustic velocity regions are further provided on the respective outer side portions of the first and second low acoustic velocity regions L1 and L2, thus suppressing a ripple caused by a transverse mode. Such a structure for suppressing a transverse mode is similar to that in a case of the acoustic wave device described in International Publication No. 2015/098756.

As illustrated in FIG. 1A, the reflectors 8 and 9 each have a structure in which both ends of a plurality of electrode fingers are short-circuited by respective busbars. In each of the reflectors 8 and 9 as well, the respective busbars on both sides are inclined similarly to the first and second busbars 11 and 12.

The inclined IDT electrode described above is also disclosed in International Publication No. 2015/098756. In addition, in the acoustic wave device described in International Publication No. 2015/098756, a large-width portion is provided at a tip end of each of first and second electrode fingers in order to suppress a transverse mode. However, the inventor of the present application has discovered that a ripple appears between a resonant frequency and an anti-resonant frequency due to the provision of such a large-width portion.

In the acoustic wave device 1, it is possible to suppress the ripple between the resonant frequency and the anti-resonant frequency. This is possible because the projecting portion 17 is provided at each of the first electrode finger 13, the second electrode finger 14, the first dummy electrode 15, and the second dummy electrode 16. This will be described in more detail.

As illustrated in FIG. 1B, the first electrode finger 13 includes a first side 13a and a second side 13b, and the second electrode finger 14 includes a first side 14a and a second side 14b. A1so, the first dummy electrode 15 includes a first side 15a and a second side 15b, and the second dummy electrode 16 includes a first side 16a and a second side 16b.

A direction in which the first busbar 11 is inclined downward relative to the horizontal direction in FIG. 2 is an inclination direction. As described above, the IDT electrode 7 has the inclined structure. Accordingly, a distance between a tip end of the second electrode finger 14 on one side, of the second electrode fingers 14 adjacent to any first electrode finger 13, and a base end of the first electrode finger 13 is shorter than a distance between a tip end of the second electrode finger 14 on the other side and the base end. In the present preferred embodiment, a side closer to the second electrode finger 14 for which the distance is shorter, of sides of the first electrode finger 13, is the first side 13a. A side closer to the second electrode finger 14 for which the distance is shorter, of sides of the first dummy electrode 15 facing the first electrode finger 13, is the first side 15a. A side opposite to the first side 13a is the second sides 13b and a side opposite to the first side 15a is the second side 15b. Similarly, a distance between a tip end of the first electrode finger 13 on one side, of the first electrode fingers 13 adjacent to any second electrode finger 14, and a base end of the second electrode finger 14 is shorter than a distance between a tip end of the first electrode finger 13 on the other side and the base end. In the present preferred embodiment, a side closer to the first electrode finger 13 for which the distance is shorter, of sides of the second electrode finger 14, is the second side 14b. A side closer to the first electrode finger 13 for which the distance is shorter, of sides of the second dummy electrode 16 facing the second electrode finger 14, is the second side 16b. A side opposite to the second side 14b is the first side 14a, and a side opposite to the second side 16b is the first side 16a.

As illustrated in FIG. 2, of a portion closer to the first gap G1 of the second dummy electrodes 16, a region closer to the first side 16a is a first region R1 and a region closer to the second side 16b is a second region R2. Of the second electrode finger 14 facing the first gap G1, a region closer to the first side 14a is a fifth region R5 and a region closer to the second side 14b is a sixth region R6. In the first electrode finger 13 adjacent in the inclination direction to the second dummy electrode 16, in a portion on the side closer to the first busbar 11 with respect to the second virtual line B, a region closer to the first side 13a is a third region R3 and a region closer to second side 13b is a fourth region R4, in the first electrode finger 13, in a portion on the side closer to the second busbar 12 with respect to the second virtual line B, a region closer to the first side 13a is a seventh region R7 and a region closer to the second side 13b is an eighth region R8.

In the first region R1 and the third region R3, an angle F2 defined by each of the first sides 16a and 13a positioned in the respective regions, and the first virtual line A is an acute angle. Similarly, in the sixth region R6 and the eighth region R8, the angle F2 defined by each of the second sides 14b and 13b positioned in the respective regions, and the first virtual line A is an acute angle.

On the other hand, in the second region R2 and the fourth region R4, an angle F1 defined by each of the second sides 16b and 13b and the first virtual line A is an obtuse angle. Similarly, in the fifth region R5 and the seventh region R7, the angle F1 defined by each of the first sides 14a and 13a and the first virtual line A is an obtuse angle.

Here, the angle defined by the first side or the second side and the first virtual line A in each of the first to eighth regions R1 to R8 refers to an intersection angle in a portion positioned in each of the first to eighth regions R1 to R8. Further, the angle in each region refers to an intersection angle closer to the region, between a portion of the first side or the second side positioned in each region and the first virtual line A.

In a preferred embodiment of the present invention, at least one of, at least one recessed portion provided in at least one region of the first region R1, the third region R3, the sixth region R6, and the eighth region R8, and at least one projecting portion provided in at least one region of the second region R2, the fourth region R4, the fifth region R5 and the seventh region R7, is provided. In other words, at least one of, a projecting portion protruding toward a first electrode finger or a second electrode finger, in at least one of a side opposite to an inclination direction at a tip end of the second electrode finger, a side in the inclination direction at a tip end of a second dummy electrode, a side in the inclination direction of the first electrode finger positioned on an extension in the inclination direction from the tip end of the second dummy electrode, and a side opposite to the inclination direction of the first electrode finger positioned on an extension in the inclination direction from the tip end of the second electrode finger, and a recessed portion provided in at least one of a side in the inclination direction at the tip end of the second electrode finger, a side opposite to the inclination direction at the tip end of the second dummy electrode, a side opposite to the inclination direction of the first electrode finger positioned on the extension in the inclination direction from the tip end of the second dummy electrode, and a side in the inclination direction of the first electrode finger positioned on the extension in the inclination direction from the tip end of the second electrode finger, is provided. As a result, it is possible to suppress ripples between the resonant frequency and the anti-resonant frequency.

In the present preferred embodiment, as illustrated in FIGS. 1A and 1B, the projecting portion 17 is provided as the recessed portion or projecting portion. More specifically, in the second side 16b of the second dummy electrode 16, the projecting portion 17 protruding toward the first electrode finger 13 is provided. That is, the projecting portion 17 is provided in the second region R2. Similarly, the projecting portion 17 is provided also in the fifth region R5.

In the existing acoustic wave device, a low acoustic velocity region was defined by providing the large-width portion at the tip end of the electrode finger. A displacement distribution in this case will be described with reference to FIG. 5. FIG. 5 is a schematic plan view illustrating an enlarged portion of an electrode structure of an existing acoustic wave device 100. Here, a large-width portion 102a is provided at a tip end of a second electrode finger 102. Further, a tip end of a second dummy electrode 104 is also provided with a large-width portion 104a.

The large-width portion 102a and the large-width portion 104a face each other with the first gap G1 interposed therebetween. In this case, when a first electrode finger 101 connected to a first busbar becomes a hot side, since an IDT electrode has an inclined structure, a region where displacement on a positive potential side is large is a region H1 illustrated by hatching. On the other hand, a region where displacement on a negative potential side is large is a region H2 indicated by hatching.

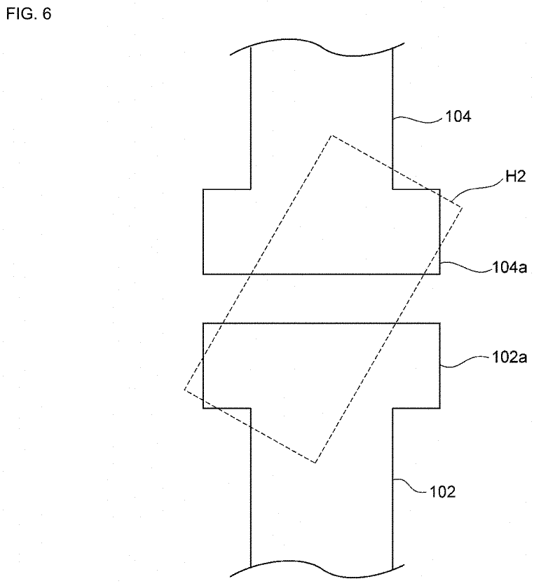

As is apparent from FIG. 5, since the IDT electrode has the inclined structure, the portion having the large displacement is inclined with respect to a direction in which the first and second electrode fingers 101 and 102 extend. That is, as further enlarged and illustrated in FIG. 6, the region H2 schematically illustrated is positioned in a region inclined with respect to a direction in which the second electrode finger 102 and the second dummy electrode 104 extend. Thus, it is considered that, when the large-width portion 102a or 104a is provided symmetrically about a central axis passing in a length direction of the second electrode finger 102 or the second dummy electrode 104, the above-described ripple appears due to shifting from the inclination angles of the respective regions H1 and H2.

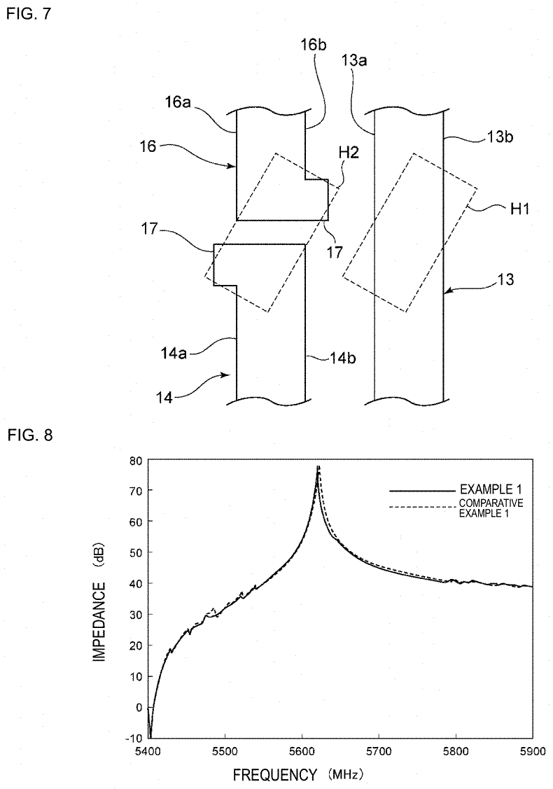

On the other hand, as illustrated in FIG. 7, in the present preferred embodiment, for example, the projecting portion 17 is provided in each of the second region R2 and the fifth region R5 to adapt to the inclination of the region H2. Thus, the above-described ripple due to the transverse mode is suppressed. This will be described based on a specific experimental example.

An acoustic wave device of Comparative Example 1 was configured based on the existing acoustic wave device described above, and an acoustic wave device of Example 1 was manufactured that was configured similarly to Comparative Example 1 except that the projecting portion 17 was provided instead of the large-width portion. Design parameters of the acoustic wave device of Example 1 were as follows.

A layer configuration of the piezoelectric substrate 2, materials of each layer, thicknesses of each layer: piezoelectric film/low acoustic velocity material layer/high acoustic velocity support substrate, LiTaO₃/SiO₂/Si, 0.350 μm/0.450 μm/250 μm.

A material of the IDT electrode 7 and the reflectors 8 and 9: Al. A thickness=60 nm.

A wavelength λ determined by an electrode finger pitch of the IDT electrode 7=0.7 μm.

The number of pairs of electrode fingers: a one pair model was configured to have an infinite period by a boundary condition.

An angle defined by the first virtual line A and the acoustic wave propagation direction D=5°.

A dimension of each of the first and second gaps G1 and G2 in a direction in which an electrode finger extends=0.28 μm.

An amount of protrusion of the projecting portion 17 from a first side or a second side=0.07 μm.

A dimension of the projecting portion 17 in the direction in which the electrode finger extends=0.2 μm.

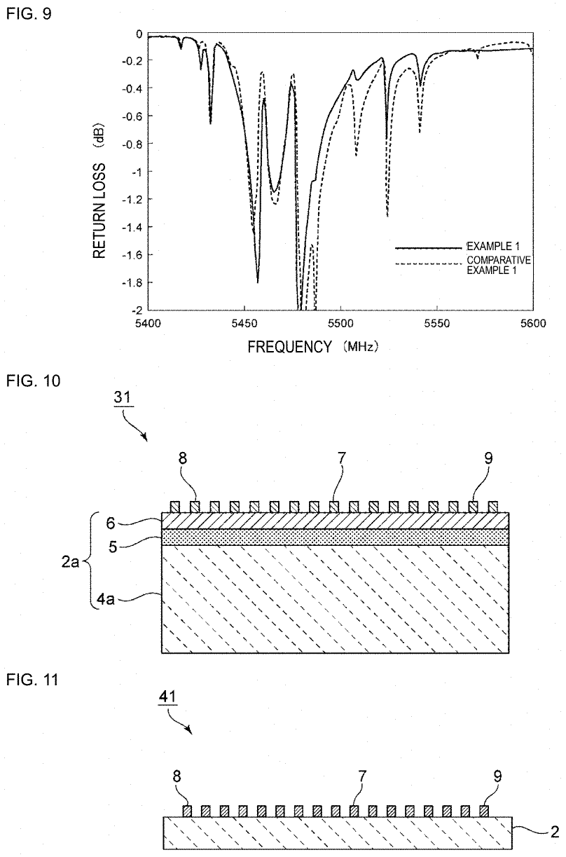

FIG. 8 shows impedance-frequency characteristics of the acoustic wave devices of Comparative Example 1 and Example 1 described above, and FIG. 9 shows return loss characteristics. Note that, in each of FIG. 8 and FIG. 9, a solid line shows a result of Example 1 and a broken line shows a result of Comparative Example 1.

As is clear from FIG. 8 and FIG. 9, in Comparative Example 1, a plurality of large ripples appears between a resonant frequency and an anti-resonant frequency. On the other hand, according to Example 1, such ripples are effectively suppressed. Thus, according to Example 1, since the configuration was adopted in which the projecting portion 17 was provided such that a large-width portion of a tip end of each of the second electrode finger 14 and the second dummy electrode 16 was not symmetric, ripples between the resonant frequency and the anti-resonant frequency could be effectively suppressed.

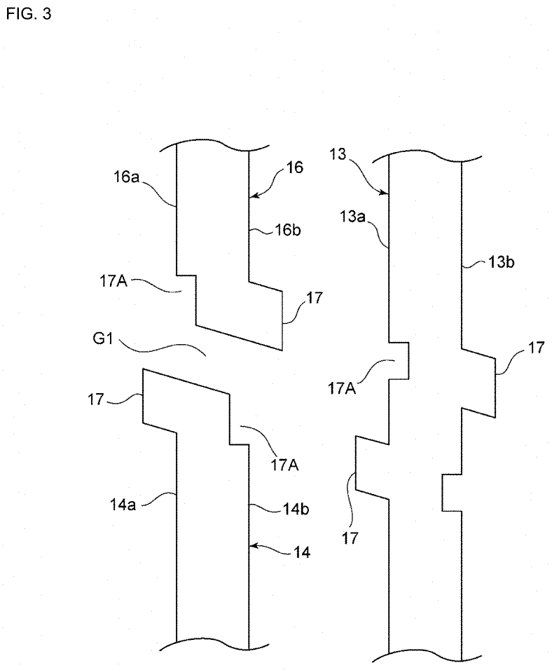

Note that, as is clear from the regions H2 and H1 illustrated in FIG. 7, instead of providing the projecting portion 17, conversely, it is desirable to provide a recessed portion in the first region R1, the sixth region R6, the third region R3, and the eighth region R8. Thus, as in a modified example illustrated in FIG. 3, it is preferable to further provide a recessed portion 17A closer to the second side 14b on a tip end side of the second electrode finger 14, and the recessed portion 17A closer to the first side 16a in the second dummy electrode 16 as well.

However, in a preferred embodiment of the present invention, it is not necessary to provide the projecting portion 17 or the recessed portion 17A in all of the first to eighth regions R1 to R8. As described above, a projecting portion may be provided in at least one region of regions where a projecting portion is desirably provided, and a recessed portion may be provided in at least one region of regions where the recessed portion 17A is desirably provided. In addition, it is sufficient that the projecting portion 17 or the recessed portion 17A is provided in at least one region of the first to eighth regions R1 to R8.

Further, the first to eighth regions R1 to R8 are illustrated for the side of the first gap G1, but similarly for a side of the second gap G2, it is sufficient that the first to eighth regions R1 to R8 are defined, and the projecting portion 17 or the recessed portion 17A is provided. That is, as illustrated in FIG. 2, the first to eighth regions R1 to R8 are defined based on the fourth virtual line B1 connecting the centers of the second gaps G2 and the third virtual line A1 connecting the tip ends of the plurality of first electrode fingers 13. At least one of the projecting portion 17 and the recessed portion 17A described above is preferably provided in the first to eighth regions R1 to R8. In other words, preferably, at least one of, a projecting portion protruding toward a first electrode finger or a second electrode finger in at least one of a side in an inclination direction at a tip end of the first electrode finger, a side opposite to the inclination direction at a tip end of a first dummy electrode, a side opposite to the inclination direction of the second electrode finger positioned on an extension opposite to the inclination direction from the tip end of the first dummy electrode, and a side in the inclination direction of the second electrode finger positioned on an extension opposite to the inclination direction from the tip end of the first electrode finger, and a recessed portion provided in at least one of a side opposite to the inclination direction at the tip end of the first electrode finger, a side in the inclination direction at the tip end of the first dummy electrode, a side in the inclination direction of the second electrode finger positioned on the extension opposite to the inclination direction from the tip end of the first dummy electrode, and a side opposite to the inclination direction of the second electrode finger positioned on the extension opposite to the inclination direction from the tip end of the first electrode finger, is provided.

Note that, on the second gap G2 side, in the first region R1, the third region R3, the sixth region R6, and the eighth region R8, an angle defined by the first side 13a or 14a, or the second side 14b or 15b, and the third virtual line A1 is an acute angle, and in the second region R2, the fourth region R4, the fifth region R5, and the seventh region R7, an angle defined by the second side 13b or 14b, or the first side 14a or 15a, and the third virtual line A1 is an obtuse angle. Thus, it is sufficient that, a recessed portion is provided in at least one region of the first region R1, the third region R3, the sixth region R6, and the eighth region R8, and a projecting portion is provided in at least one region of the second region R2, the fourth region R4, the fifth region R5, and the seventh region R7.

Furthermore, preferably, as in the modified example illustrated in FIG. 3, in the second region R2 and the third region R3 facing each other in an acoustic wave propagation direction, when the projecting portion 17 is provided in the second region R2, the recessed portion 17A is preferably provided in the third region R3. As a result, a distance between the second dummy electrode 16 and the first electrode finger 13 along the acoustic wave propagation direction can be increased. Accordingly, surge resistance can be enhanced. Thus, a projecting portion and a recessed portion are preferably provided in at least one of a portion where the second region R2 and the third region R3 face each other and a portion where the sixth region R6 and the seventh region R7 face each other. To be more specific, the IDT electrode preferably has at least one of a configuration in which a projecting portion is provided in the second region R2 and a recessed portion is provided in the third region R3, and a configuration in which a recessed portion is provided in the sixth region R6 and a projecting portion is provided in the seventh region R7.

Note that, in the modified example illustrated in FIG. 3, a tip end portion of an electrode finger including the projecting portion 17 and the recessed portion 17A has a parallelogram shape. As described above, the shape of the tip end portion of the electrode finger including the projecting portion 17 and the recessed portion 17A in preferred embodiments of the present invention is not limited to a rectangle but may be a parallelogram.

FIG. 10 is a front sectional view for describing an acoustic wave device according to a second preferred embodiment of the present invention. In an acoustic wave device 31, a high acoustic velocity material layer 4a also defines and functions as a support substrate. That is, the high acoustic velocity material layer 4a is a high acoustic velocity support substrate made of a high acoustic velocity material. In this case, the support substrate 3 illustrated in FIG. 4 can be omitted. Such a piezoelectric substrate 2a may be used.

Furthermore, the low acoustic velocity material layer 5 may be omitted in FIG. 4 and FIG. 10.

Further, FIG. 11 is a front sectional view for describing an acoustic wave device according to a third preferred embodiment of the present invention. In an acoustic wave device 41, the piezoelectric substrate 2 is a single-plate piezoelectricity substrate made of a piezoelectric single crystal such as LiNbO₃. In a preferred embodiment of the present invention, the piezoelectric substrate 2 may be formed by using such a single-plate piezoelectricity substrate.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device, comprising:
a piezoelectric substrate; and
an IDT electrode on the piezoelectric substrate; wherein the IDT electrode includes:
a first busbar;
a second busbar separated from the first busbar;
a plurality of first electrode fingers including one end connected to the first busbar, a plurality of second electrode fingers including one end connected to the second busbar;
a plurality of first dummy electrodes connected to the second busbar, tip ends of the first dummy electrodes facing tip ends of the first electrode fingers with a second gap interposed therebetween; and
a plurality of second dummy electrodes connected to the first busbar, tip ends of the second dummy electrodes facing tip ends of the second electrode fingers with a first gap interposed therebetween; and
when a first virtual line connecting the tip ends of the plurality of second electrode fingers is inclined with respect to an acoustic wave propagation direction that is a direction orthogonal to a direction in which the first and second electrode fingers extend, a distance between a tip end of a second electrode finger on one side, of a pair of second electrode fingers included in the second electrode fingers adjacent to any first electrode finger included in the first electrode fingers, and a base end of the first electrode finger is shorter than a distance between a tip end of the second electrode finger on another side of the pair and the base end of the first electrode finger, and a direction extending in a direction in which the distance is longer in the first virtual line is an inclination direction;
the acoustic wave device further comprising at least one of:
a projecting portion protruding toward the first electrode finger or the second electrode finger, in at least one of a side opposite to the inclination direction at a tip end of the second electrode finger, a side in the inclination direction at a tip end of the second dummy electrode, a side in the inclination direction of the first electrode finger positioned on an extension in the inclination direction from the tip end of the second dummy electrode, and a side opposite to the inclination direction of the first electrode finger positioned on an extension in the inclination direction from the tip end of the second electrode finger; and
a recessed portion provided in at least one of a side in the inclination direction at the tip end of the second electrode finger, a side opposite to the inclination direction at the tip end of the second dummy electrode, a side opposite to the inclination direction of the first electrode finger positioned on the extension in the inclination direction from the tip end of the second dummy electrode, and a side in the inclination direction of the first electrode finger positioned on the extension in the inclination direction from the tip end of the second electrode finger.

2. The acoustic wave device according to claim 1, wherein a third virtual line connecting the tip ends of the plurality of first electrode fingers is inclined with respect to the acoustic wave propagation direction, a distance between a tip end of a first electrode finger on one side, of a pair of first electrode fingers included in the first electrode fingers adjacent to any second electrode finger included in the second electrode fingers, and a base end of the second electrode finger is shorter than a distance between a tip end of the first electrode finger on another side of the pair and the base end of the second electrode finger, a side closer to the first electrode finger for which the distance is shorter, of sides of the second electrode finger, and a side closer to the first electrode finger for which the distance is shorter, of sides of the second dummy electrode facing the second electrode finger, are each a first side, and a side opposite to the first side is a second side;
a distance between a tip end of a second electrode finger on one side, of a pair of second electrode fingers included in the second electrode fingers adjacent to any first electrode finger included in the first electrode fingers, and a base end of the first electrode finger is shorter than a distance between a tip end of the second electrode finger on an other side of the pair and the base end of the first electrode finger, a side closer to the second electrode finger for which the distance is shorter, of sides of the first electrode finger, and a side closer to the second electrode finger for which the distance is shorter, of sides of a first dummy electrode included in the first dummy electrodes facing the first electrode finger, are each a second side, and a side opposite to the second side is a first side;
a line connecting respective centers of second gaps, each of which is the second gap interposed between the tip ends, is a fourth virtual line; and
the acoustic wave device further comprises at least one of:
a projecting portion protruding toward the first electrode finger or the second electrode finger, in at least one of a side in the inclination direction at a tip end of the first electrode finger, a side opposite to the inclination direction at a tip end of the first dummy electrode, a side opposite to the inclination direction of the second electrode finger positioned on an extension opposite to the inclination direction from the tip end of the first dummy electrode, and a side in the inclination direction of the second electrode finger positioned on an extension opposite to the inclination direction from the tip end of the first electrode finger; and
a recessed portion provided in at least one of a side opposite to the inclination direction at the tip end of the first electrode finger, a side in the inclination direction at the tip end of the first dummy electrode, a side in the inclination direction of the second electrode finger positioned on the extension opposite to the inclination direction from the tip end of the first dummy electrode, and a side opposite to the inclination direction of the second electrode finger positioned on the extension opposite to the inclination direction from the tip end of the first electrode finger.

3. The acoustic wave device according to claim 1, wherein the piezoelectric substrate includes a piezoelectric film, and a high acoustic velocity material layer made of a high acoustic velocity material by which an acoustic velocity of a bulk wave propagating through the high acoustic velocity material layer is higher than an acoustic velocity of an acoustic wave propagating through the piezoelectric film.

4. The acoustic wave device according to claim 3, further comprising a low acoustic velocity material layer laminated between the high acoustic velocity material layer and the piezoelectric film, and made of a low acoustic velocity material by which an acoustic velocity of a bulk wave propagating through the low acoustic velocity material layer is lower than an acoustic velocity of a bulk wave propagating through the piezoelectric film.

5. The acoustic wave device according to claim 3, wherein the high acoustic velocity material layer is a high acoustic velocity support substrate made of the high acoustic velocity material.

6. The acoustic wave device according to claim 1, wherein the piezoelectric substrate is a piezoelectricity substrate made of a piezoelectric single crystal.

7. The acoustic wave device according to claim 6, wherein the piezoelectric single crystal is a LiTa03.

8. An acoustic wave device, comprising:
a piezoelectric substrate; and
an IDT electrode on the piezoelectric substrate; wherein the IDT electrode includes:
a first busbar;
a second busbar separated from the first busbar;
a plurality of first electrode fingers including one end connected to the first busbar, a plurality of second electrode fingers including one end connected to the second busbar;
a plurality of first dummy electrodes connected to the second busbar, tip ends of the first dummy electrodes facing tip ends of the first electrode fingers with a second gap interposed therebetween; and
a plurality of second dummy electrodes connected to the first busbar, tip ends of the second dummy electrodes facing tip ends of the second electrode fingers with a first gap interposed therebetween;
a first virtual line connecting the tip ends of the plurality of second electrode fingers is inclined with respect to an acoustic wave propagation direction that is a direction orthogonal to a direction in which the first and second electrode fingers extend;
a distance between a tip end of a second electrode finger on one side, of a pair of second electrode fingers included in the second electrode fingers adjacent to any first electrode finger included in the first electrode fingers, and a base end of the first electrode finger is shorter than a distance between a tip end of the second electrode finger on an other side of the pair and the base end of the first electrode finger, a side closer to the second electrode finger for which the distance is shorter, of sides of the first electrode finger, and a side closer to the second electrode finger for which the distance is shorter, of sides of a first dummy electrode included in the first dummy electrodes facing the first electrode finger, are each a first side, and a side opposite to the first side is a second side;
a distance between a tip end of a first electrode finger on one side, of a pair of first electrode fingers included in the first electrode fingers adjacent to any second electrode finger included in the second electrode fingers, and a base end of the second electrode finger is shorter than a distance between a tip end of the first electrode finger on an other side of the pair and the base end of the second electrode finger, a side closer to the first electrode finger for which the distance is shorter, of sides of the second electrode finger, and a side closer to the first electrode finger for which the distance is shorter, of sides of a second dummy electrode included in the second dummy electrodes facing the second electrode finger, are each a second side, and a side opposite to the second side is a first side;
a line connecting respective centers of first gaps, each of which being the first gap interposed between the tip ends, is a second virtual line;
of a portion closer to the first gap of the second dummy electrode, a region closer to the first side is a first region and a region closer to the second side is a second region, of a portion closer to the first gap of the second electrode finger, a region closer to the first side is a fifth region and a region closer to the second side is a sixth region, and in the first electrode finger that is adjacent, in a portion closer to the first busbar with respect to the second virtual line, a region closer to the first side is a third region and a region closer to the second side is a fourth region, and in the first electrode finger, in a portion closer to the second busbar with respect to the second virtual line, a region closer to the first side is a seventh region and a region closer to the second side is an eighth region;
in the first region, the third region, the sixth region, and the eighth region, an angle defined by the first side or the second side in each region, and the first virtual line is an acute angle, and in the second region, the fourth region, the fifth region, and the seventh region, an angle defined by the first side or the second side positioned in each region, and the first virtual line is an obtuse angle; and
at least one of a recessed portion provided in at least one region of the first region, the third region, the sixth region, and the eighth region, and a projecting portion provided in at least one region of the second region, the fourth region, the fifth region, and the seventh region is provided.

9. The acoustic wave device according to claim 8, wherein
an intersection region that is a region in which the first electrode finger and the second electrode finger overlap when viewed in the acoustic wave propagation direction includes a central region positioned at a center in the direction in which the first and second electrode fingers extend, and first and second low acoustic velocity regions provided on both outer side portions of the central region; and
the recessed portion or the projecting portion is provided in the first and second low acoustic velocity regions.

10. The acoustic wave device according to claim 8, further comprising:
the recessed portion provided in at least one region of the first region, the third region, the sixth region, and the eighth region; and
the projecting portion provided in at least one region of the second region, the fourth region, the fifth region, and the seventh region.

11. The acoustic wave device according to claim 10, further comprising:
the projecting portion provided in the second region and the fifth region; and
the recessed portion provided in the first region and the sixth region.

12. The acoustic wave device according to claim 11, wherein in at least one of a portion in which the second region and the third region face each other in the acoustic wave propagation direction and a portion in which the sixth region and the seventh region face each other in the acoustic wave propagation direction, the projecting portion is provided in the second region and the seventh region, and the recessed portion is provided in the third region and the sixth region.

13. The acoustic wave device according to claim 8, wherein a third virtual line connecting the tip ends of the plurality of first electrode fingers is inclined with respect to the acoustic wave propagation direction, a distance between a tip end of a first electrode finger on one side, of a pair of first electrode fingers included in the first electrode fingers adjacent to any second electrode finger included in the second electrode fingers, and a base end of the second electrode finger is shorter than a distance between a tip end of the first electrode finger on another side of the pair and the base end of the second electrode finger, a side closer to the first electrode finger for which the distance is shorter, of sides of the second electrode finger, and a side closer to the first electrode finger for which the distance is shorter, of sides of the second dummy electrode facing the second electrode finger, are each a first side, and a side opposite to the first side is a second side;
a distance between a tip end of a second electrode finger on one side, of a pair of second electrode fingers included in the second electrode fingers adjacent to any first electrode finger included in the first electrode fingers, and a base end of the first electrode finger is shorter than a distance between a tip end of the second electrode finger on an other side of the pair and the base end of the first electrode finger, a side closer to the second electrode finger for which the distance is shorter, of sides of the first electrode finger, and a side closer to the second electrode finger for which the distance is shorter, of sides of a first dummy electrode included in the first dummy electrodes facing the first electrode finger, are each a second side, and a side opposite to the second side is a first side;
a line connecting respective centers of second gaps, each of which is the second gap interposed between the tip ends, is a fourth virtual line; and
the acoustic wave device further comprises at least one of:
a projecting portion protruding toward the first electrode finger or the second electrode finger, in at least one of a side in the inclination direction at a tip end of the first electrode finger, a side opposite to the inclination direction at a tip end of the first dummy electrode, a side opposite to the inclination direction of the second electrode finger positioned on an extension opposite to the inclination direction from the tip end of the first dummy electrode, and a side in the inclination direction of the second electrode finger positioned on an extension opposite to the inclination direction from the tip end of the first electrode finger; and
a recessed portion provided in at least one of a side opposite to the inclination direction at the tip end of the first electrode finger, a side in the inclination direction at the tip end of the first dummy electrode, a side in the inclination direction of the second electrode finger positioned on the extension opposite to the inclination direction from the tip end of the first dummy electrode, and a side opposite to the inclination direction of the second electrode finger positioned on the extension opposite to the inclination direction from the tip end of the first electrode finger.

14. The acoustic wave device according to claim 8, wherein a third virtual line connecting the tip ends of the plurality of first electrode fingers is inclined with respect to the acoustic wave propagation direction, a distance between a tip end of a first electrode finger on one side, of a pair of first electrode fingers included in the first electrode fingers adjacent to any second electrode finger included in the second electrode fingers, and a base end of the second electrode finger is shorter than a distance between a tip end of the first electrode finger on another side of the pair and the base end of the second electrode finger, a side closer to the first electrode finger for which the distance is shorter, of sides of the second electrode finger, and a side closer to the first electrode finger for which the distance is shorter, of sides of the second dummy electrode facing the second electrode finger, are each a first side, and a side opposite to the first side is a second side;
a distance between a tip end of a second electrode finger on one side, of a pair of second electrode fingers included in the second electrode fingers adjacent to any first electrode finger included in the first electrode fingers, and a base end of the first electrode finger is shorter than a distance between a tip end of the second electrode finger on another side of the pair and the base end of the first electrode finger, a side closer to the second electrode finger for which the distance is shorter, of sides of the first electrode finger, and a side closer to the second electrode finger for which the distance is shorter, of sides of a first dummy electrode included in the first dummy electrodes facing the first electrode finger, are each a second side, and a side opposite to the second side is a first side;
a line connecting respective centers of second gaps, each of which is the second gap interposed between the tip ends, is a fourth virtual line;
of a portion closer to the second gap of the first dummy electrode, a region closer to the second side is a first region and a region closer to the first side is a second region, of a portion closer to the second gap of the first electrode finger, a region closer to the second side is a fifth region and a region closer to the first side is a sixth region, and in the second electrode finger that is adjacent, in a portion closer to the second busbar with respect to the fourth virtual line, a region closer to the second side is a third region and a region closer to the first side is a fourth region, and in the second electrode finger, in a portion closer to the first busbar with respect to the fourth virtual line, a region closer to the second side is a seventh region and a region closer to the first side is an eighth region;
in the first region, the third region, the sixth region, and the eighth region, an angle defined by the first side or the second side in each region, and the third virtual line is an acute angle, and in the second region, the fourth region, the fifth region, and the seventh region, an angle defined by the first side or the second side positioned in each region, and the third virtual line is an obtuse angle; and
the acoustic wave device further comprises at least one of:
the recessed portion provided in at least one region of the first region, the third region, the sixth region, and the eighth region; and
the projecting portion provided in at least one region of the second region, the fourth region, the fifth region, and the seventh region.

15. The acoustic wave device according to claim 8, wherein the piezoelectric substrate includes a piezoelectric film, and a high acoustic velocity material layer made of a high acoustic velocity material by which an acoustic velocity of a bulk wave propagating through the high acoustic velocity material layer is higher than an acoustic velocity of an acoustic wave propagating through the piezoelectric film.

16. The acoustic wave device according to claim 15, further comprising a low acoustic velocity material layer laminated between the high acoustic velocity material layer and the piezoelectric film, and made of a low acoustic velocity material by which an acoustic velocity of a bulk wave propagating through the low acoustic velocity material layer is lower than an acoustic velocity of a bulk wave propagating through the piezoelectric film.

17. The acoustic wave device according to claim 15, wherein the high acoustic velocity material layer is a high acoustic velocity support substrate made of the high acoustic velocity material.

18. The acoustic wave device according to claim 8, wherein the piezoelectric substrate is a piezoelectricity substrate made of a piezoelectric single crystal.

19. The acoustic wave device according to claim 18, wherein the piezoelectric single crystal is a LiTaO₃.
